(19) United States
(12) Patent Application Publication
(10) Pub. No.: US 2006/0012009 A1
(43) Pub. Date: Jan. 19, 2006

(54) Semiconductor device

(76) Inventor: Tadashi Chiba, Tokyo (JP)

Correspondence Address: TAKEUCHI & TAKEUCHI, Suite 310, 1700 Diagonal Road, Alexandria, VA, 22314, US

(21) Appl. No.: 11/070,248

(22) Filed: Mar. 3, 2005

(30) Foreign Application Priority Data
Jul. 14, 2004 (JP) 2004-207138

(51) Int. Cl. H01L 29/93

(52) U.S. Cl. 257/595

(57) ABSTRACT

A semiconductor device includes a variable capacitance diode. The variable capacitance diode includes a semiconductor substrate having a circuit area; a plurality of diffusion areas formed on the semiconductor substrate in the circuit area; a gate oxide layer formed in a gate area between the diffusion areas; a control electrode formed on the gate oxide layer; an insulating layer formed on the diffusion areas and the control electrode; a first contact formed in the insulating layer and passing through the insulating layer; a first wiring pattern electrically connected to the diffusion areas through the first contact; a second contact formed in the insulating layer and passing through the insulating layer; and a second wiring layer electrically connected to the control electrode through the second contact. The gate oxide layer has a first area with a first thickness and a second area with a second thickness different from the first thickness.

### BACKGROUND OF THE INVENTION AND RELATED ART STATEMENT

The present invention relates to a semiconductor device having a variable capacitance diode as a circuit element.

A variable capacitance diode is called a varactor in which a capacitance is changed according to a direct current voltage applied between electrodes thereof. The variable capacitance diode is used for controlling a frequency as a circuit element of a voltage control oscillator (VCO) in a phase locked loop (PLL). The variable capacitance diode in a semiconductor integrated circuit is generally produced with a process similar to those of MOS transistors. That is, a source electrode is connected to a drain electrode, and a gate oxide layer formed with a gate electrode in between generates a capacitance as a capacitor.

FIG. 2 is a schematic view showing a general configuration of a semiconductor integrated circuit with the variable capacitance diode. The semiconductor integrated circuit has a plurality of input terminals 1 for receiving external signals including clock signals CLK, and the input terminals 1 are connected to an inner circuit 3 via an input circuit 2. The inner circuit 3 performs a specific logical calculation process according to an external signal applied to the input terminals 1, and is formed of a combination of logic gates formed of several MOS transistors and the like.

The inner circuit 3 has VCO and PLL (not shown) synchronizing the clock signal CLK received from outside, so that an internal clock signal with a frequency different from that of the clock signal CLK is generated. A variable capacitance diode 4 is used in VCO as a capacitor of, for example, an LC resonant circuit formed of a coil and a capacitor. A variable direct current voltage is applied to a control electrode of the variable capacitance diode 4 for controlling an oscillating frequency. A result signal obtained in the login circuit 3 is sent to output terminals 6 via an output circuit 5.

The input circuit 2 protects the inner circuit 3 from a static surge voltage entering through the input terminals 1. The input circuit 2 has a protection diode connected between the input terminals 1, and a power source terminal and a ground terminal (not shown). The input circuit 2 also has a buffer amplifier for sending an input signal to the inner circuit 3. Similarly, the output circuit 5 has a buffer amplifier for protecting the inner circuit 3 from a static surge voltage entering through the output terminals 6.

The buffer amplifiers in the input circuit 2 and the output circuit 5 are formed of transistors with a gate oxide layer having a thickness larger than that of those in the inner circuit 3 for preventing breakdown due to a static surge voltage and the like. For example, a transistor in the inner circuit 3 may have a gate oxide layer with a thickness of 2.5 nm, while a transistor in the input circuit 2 or the output circuit 5 may have a gate oxide layer with a thickness of 5.0 nm. Similar to the transistor in the inner circuit 3, the variable capacitance diode 4 may have a gate oxide layer with a thickness of 2.5 nm. A pattern of the variable capacitance diode 4 is designed to have an area enough for obtaining a necessary capacitance according to a variable range of an oscillating frequency of VCO.

Patent Reference 1; U.S. Pat. No. 6,608,747

Patent Reference 2; Japanese Patent Publication (Kokai) No. 2000-223722.

In the semiconductor devices described above, when the oscillating frequency of VCO is changed, it is necessary to change an area of the variable capacitance diode 4. Accordingly, even though a circuit configuration is the same, it is necessary to change a circuit pattern according to the oscillating frequency.

In view of the problems described above, an object of the present invention is to provide a semiconductor device in which it is possible to arbitrarily change an oscillating frequency of VCO disposed therein without changing a circuit pattern.

Further objects and advantages of the invention will be apparent from the following description of the invention.

### SUMMARY OF THE INVENTION

In order to attain the objects described above, according to a first aspect of the present invention, a semiconductor device includes a variable capacitance diode. The variable capacitance diode includes a semiconductor substrate having a circuit area; a plurality of diffusion areas formed on the semiconductor substrate in the circuit area; a gate oxide layer formed in a gate area between the diffusion areas in the circuit area; a control electrode formed on the gate oxide layer; an insulating layer formed on the diffusion areas and the control electrode; a first contact formed in the insulating layer and passing through the insulating layer; a first wiring pattern electrically connected to the diffusion areas through the first contact; a second contact formed in the insulating layer and passing through the insulating layer; and a second wiring layer electrically connected to the control electrode through the second contact. The gate oxide layer has a first area with a first thickness and a second area with a second thickness different from the first thickness.

In the present invention, the variable capacitance diode is an MOS type, and has the gate oxide layer divided into the first area with the first thickness and the second area with the second thickness. Accordingly, it is possible to change a range of a capacitance by changing a ratio of the first area and the second area without changing a pattern of the variable capacitance diode.

### BRIEF DESCRIPTION OF THE DRAWINGS

FIGS. 1(a) and 1(b) are views showing a variable capacitance diode according to an embodiment of the present invention, wherein FIG. 1(a) is a plan view thereof and FIG. 1(b) is a sectional view taken along line 1(b)-1(b) in FIG. 1(a); and

FIG. 2 is a schematic diagram showing a general configuration of a semiconductor device with a variable capacitance diode.

### DETAILED DESCRIPTION OF PREFERRED EMBODIMENTS

Hereunder, embodiments of the present invention will be explained with reference to the accompanying drawings. In the present invention, a variable capacitance diode has a gate oxide layer. A portion of the gate oxide layer (first area) is formed to have a thickness of 5.0 nm in a process same as that of forming a gate oxide layer of a transistor in an input or output circuit. The remaining portion of the gate oxide layer (second area) is formed to have a thickness of 2.5 nm in a process same as that of forming a gate oxide layer of a transistor in an inner circuit. In this case, an areal ratio of the first and second areas is adjusted according to a target capacitance of the variable capacitance diode.

The embodiments of the present invention will be explained to clarify the features of the invention. The drawings are used for the explanation, and do not limit the scope of the invention.

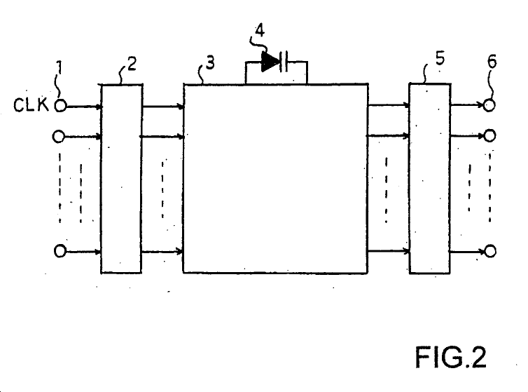

The variable capacitance diode is an MOS type and formed as a variable capacitance diode shown in FIG. 2. An n-type well 11 is formed in a p-type silicon substrate 10. Diffusion areas 12 doped with n⁺ ions are formed on the n-type well 11 in parallel with each other. A plurality of gate oxide layers 13 is formed at areas between the diffusion areas 12 in a parallel pattern. Some of the gate oxide layers 13a to 13c have a thickness of 5.0 nm same as that of gate oxide layers of transistors in the input circuit 2 and the output circuit 5. The remaining gate oxide layers 13d to 13f have a thickness of 2.5 nm same as that of a gate oxide layer of a transistor in the inner circuit 3.

Control electrodes 14 are formed on surfaces of the gate oxide layers 13a to 13f. An insulating layer 15 covers a surface of the silicon substrate 10 with the diffusion areas 12 and the control electrodes 14. A first wiring pattern 16a and a second wiring pattern 16b are formed on the insulating layer 15. The first wiring pattern 16a is electrically connected to the diffusion areas 12 through a plurality of contacts 17a. The second wiring pattern 16b is electrically connected to the control electrodes 14 through a plurality of contacts 17b.

A method of producing the variable capacitance diode will be explained next. The variable capacitance diode is produced together with the MOS transistors in the input circuit 2, the inner circuit 3, and the output circuit 5 during a manufacturing process of the semiconductor integrated circuit shown in FIG. 2.

First, the n-type well 11 is formed in the p-type silicon substrate 10 in an area where the variable capacitance diode is to be formed. Then, n-type ions are implanted into the silicon substrate 10 to form the diffusion areas 11. In the first oxide layer formation process, an oxide layer with a thickness of 4.5 nm is formed on an entire surface of the wafer.

Then, resist patterns are formed in areas to be the input circuit 2, the output circuit 5, and an area AREA to be the gate oxide layers 13a to 13c with a thickness of 5.0 nm. The oxide layer is etched with the resist patterns as a mask. As a result, the un-masked areas of the oxide layer is completely removed, i.e., areas to be the inner circuit 3 and the gate oxide layer 13d to 13f with a thickness of 2.5 nm.

After the resist patterns are removed, the second oxide layer formation process is conducted on the entire surface of the wafer, so that the areas without the oxide layer are covered with an oxide layer with a thickness of 2.5 nm. Accordingly, the oxide layer with a thickness of 2.5 nm is formed on the area to be the inner circuit 3 and the areas to be the gate oxide layers 13d to 13f. The areas to be the input circuit 2 and the output circuit 5, and the area AREA to be the gate oxide layers 13a to 13c, where the oxide layer remains in the etching process, have a thickness of 4.5 nm when the second oxide layer formation process starts. Therefore, a growth rate of the oxide layer becomes small, and only an oxide layer of 0.5 nm is additionally deposited. As a result, the oxide layers of the input circuit 2 and the output circuit 4, and the gate oxide layers 13a to 13c have a thickness of 5.0 nm.

Then, poly-silicon layers are formed and shaped to form the control electrodes 14. Further, the interlayer insulating layer 15 is formed on the entire surface of the wafer. Contact holes are formed in the interlayer insulating layer 15, and a conductive material such as aluminum is filled in the contact holes to form the contacts 17a to 17b. The first and second wiring patterns 16a and 16b are formed on the interlayer insulating layer 15.

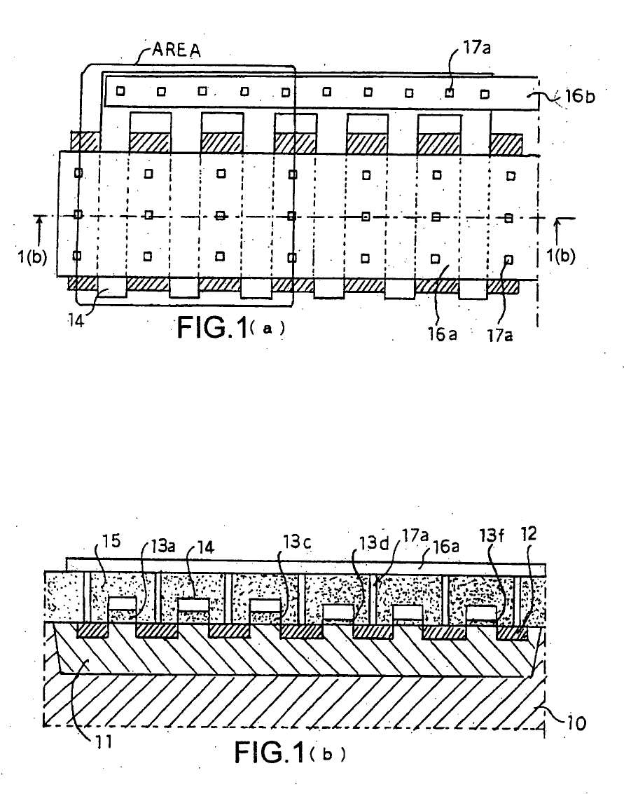

Accordingly, the variable capacitance diode shown in FIGS. 1(a) and 1(b) is produced. Although not shown in the figures, the transistors in the input circuit 2, the inner circuit 3, and the output circuit 5 are produced at the same time as is the variable capacitance diode.

As described above, in the variable capacitance diode of the embodiment, the gate oxide layers have the thickness of 5.0 nm at a part of the area and the thickness of 2.5 nm at the remaining of the area. It is possible to freely change a ratio of the two areas through a shape of the resist mask used in the oxide layer etching process. That is, an average thickness of the gate oxide layers can be varied between 2.5 nm and 5.0 nm by changing a shape of the resist mask.

When a dimension of opposing electrodes and a dielectric constant of an insulating layer between the electrodes are constant, a static capacitance is in reverse proportion to a layer thickness. Accordingly, in the variable capacitance diode of the embodiment, it is possible to change a variable range of the static capacitance without changing a shape of the electrodes.

With the variable capacitance diode of the present invention, it is possible to arbitrarily change an oscillating frequency of VCO during a manufacturing process without changing a shape of the electrodes.

In the present invention, in addition to the embodiments, various modifications are possible as follows:
(1) The diffusion area 12 may be formed through implanting p-type ions instead of n-type ions. In this case, a voltage applied to the control electrodes changes in a direction opposite to that of a change in the capacitance.
(2) Instead of the silicon substrate 10, a silicon-on-insulator (SOI) substrate or a silicon-on-sapphire may be used.
(3) The thickness of the gate oxide layers 13a to 13f is not limited to those in the embodiments. In the embodiment, a set of gate oxide layers arranged in parallel has two levels of thickness. Alternatively, a single gate oxide layer may have a thin layer and a thick layer alternately.
(4) The shapes of the gate oxide electrodes 13a to 13f and the control electrodes 14 are not limited to rectangular shapes arranged in parallel, and may be a single square.
(5) Among the gate oxide layers 13a to 13f, the large thickness corresponds to the thickness of the transistors in the input and output circuits, and the small thickness corresponds to the thickness of the transistors in the inner circuit. The present invention is not limited to the embodiment. For example, when the inner circuit has transistors with a different thickness, the gate oxide layers may correspond to the different thickness.

The disclosure of Japanese Patent Application No. 2004-207138, filed on Jul. 14, 2004, is incorporated in the application.

While the invention has been explained with reference to the specific embodiments of the invention, the explanation is illustrative and the invention is limited only by the appended claims.

What is claimed is:

1. A semiconductor device, comprising:
a variable capacitance diode, wherein said variable capacitance diode comprises:
a semiconductor substrate having a circuit area;
a plurality of diffusion areas formed on the semiconductor substrate in the circuit area;
a gate oxide layer formed in a gate area between the diffusion areas in the circuit area, said gate oxide layer having a first area with a first thickness and a second area with a second thickness different from the first thickness;
a control electrode formed on the gate oxide layer;
an insulating layer formed on the diffusion areas and the control electrode;
a first contact formed in the insulating layer and passing through the same;
a first wiring pattern electrically connected to the diffusion areas through the first contact;
a second contact formed in the insulating layer and passing through the same; and
a second wiring layer electrically connected to the control electrode through the second contact.

2. A semiconductor device according to claim 1, wherein said plurality of the diffusion areas are formed in rectangular shapes arranged such that long sides of the rectangular shapes are aligned in parallel.

3. A semiconductor device according to claim 2, wherein said plurality of the diffusion areas has the first thickness in one of the rectangular shapes or more than two adjacent rectangular shapes, and has the second thickness in a remaining one of the rectangular shapes or more than two adjacent rectangular shapes.

4. A semiconductor device according to claim 1, further comprising a first MOS transistor having a first gate oxide layer with the first thickness and a second MOS transistor having a second gate oxide layer with the second thickness.

5. A semiconductor device according to claim 4, wherein said first gate oxide layer is formed in a process of forming the first area of the gate oxide layer, and said second oxide layer is formed in a process of forming the second area of the gate oxide layer.
